(19) United States
(12) Patent Application Publication
(10) Pub. No.: US 2006/0214667 A1
(43) Pub. Date: Sep. 28, 2006

(54) Power supply system

(75) Inventor: Fuyuki Mizushima, Tokyo (JP)

Correspondence Address: EDWARDS & ANGELL, LLP, P.O. BOX 55874, BOSTON, MA, 02205, US

(73) Assignee: Yokogawa Electric Corporation, Tokyo (JP)

(21) Appl. No.: 11/389,425

(22) Filed: Mar. 23, 2006

(30) Foreign Application Priority Data
Mar. 25, 2005 (JP) 2005-087451

(51) Int. Cl. G01R 11/32; G01R 31/00

(52) U.S. Cl. 324/500; 324/142

(57) ABSTRACT

A disconnection detecting portion detects a disconnection of a power supply bus. A connecting portion connects both ends of the power supply bus when the disconnection is detected by the disconnection detecting portion. Also, a first power supplying portion is connected to one end side of the power supply bus and connected to the equipments via the power supply bus. A second power supplying portion is connected to the other end side of the power supply bus and connected to the equipments via the power supply bus. Another disconnection detecting portion detects the disconnection a communication bus. A controlling portion causes the first power supplying portion and the second power supplying portion to function when the disconnection is detected by the disconnection detecting portion.

### CROSS-REFERENCE TO RELATED APPLICATIONS

This application is based upon and claims the benefit of priority from the prior Japanese Patent Applications No. 2005-087451, filed on Mar. 25, 2005, the entire contents of which are incorporated herein by reference.

### BACKGROUND OF THE INVENTION

1. Field of the Invention

The present invention relates to a power supply system in which a power supply equipment and respective devices are connected to a power supply bus and, more particularly, a power supply system capable of dealing with a disconnection of the power supply bus.

2. Description of the Related Art

As the system for connecting field equipments such as a valve, a sensor, and the like provided to respective portions of the plant via the field bus, the field bus system based on the FOUNDATION field bus specification is known. This field bus is used as the communication bus to hold the communication between the field equipment and the upper system, or between the field equipments. Also, the power supply system for the field equipments is connected to the field bus, and the field bus functions as the power supply bus to supply a power-supply voltage to respective field equipments.

JP-A-05-218908 is referred to as a related art.

In the above system, a single power supply system is connected to respective field equipments via a common field bus. Therefore, the above system possesses the advantage that the leading of the power supply line can be reduced. However, when the field bus is cut off, the field equipments those are ahead of the cut portion run into their function halt situation and therefore an urgent recovery of the power supply system into its power supplying state is requested.

### SUMMARY OF THE INVENTION

An object of the present invention is to provide a power supply system capable of dealing adequately with a disconnection of a power supply bus.

The invention provides a power supply system in which a power supply apparatus and respective equipments are connected to a common power supply bus, includes a disconnection detecting portion which detects a disconnection of the power supply bus; and a connecting portion which connects both ends of the power supply bus when the disconnection is detected by the disconnection detecting portion.

According to this power supply system, both ends of the power supply bus are connected as soon as the disconnection is detected. Therefore, the supply of the power supply voltage to all equipments that are connected to the power supply bus can be recovered promptly.

The invention also provides a power supply system in which a power supply apparatus and respective equipments are connected to a common power supply bus, includes a first power supplying portion connected to one end side of the power supply bus and connected to the equipments via the power supply bus; a second power supplying portion connected to other end side of the power supply bus and connected to the equipments via the power supply bus; a disconnection detecting portion which detects the disconnection of the power supply bus; and a controlling portion which causes the first power supplying portion and the second power supplying portion to function when the disconnection is detected by the disconnection detecting portion.

According to this power supply system, the first power supplying portion and the second power supplying portion are caused to operate when the disconnection is detected. Therefore, the supply of the power supply voltage to all the equipments that are connected to the power supply bus can be revived immediately.

In the power supply system, the disconnection detecting portion may detect the disconnection based on a voltage of the power supply bus.

In the power supply system, the disconnection detecting portion may include a signal outputting portion which outputs a detect signal to the power supply bus from the first power supplying portion, and a signal receiving portion which receives the detect signal, which propagates through the power supply bus, from the signal outputting portion, wherein the disconnection detecting portion may detect the disconnection based on a reception result in the signal receiving portion.

According to the power supply system of the present invention, when the disconnection is detected, both ends of the power supply bus are connected mutually. Therefore, a power supply for use in all equipments that are connected to the power supply bus can be promptly revived. Also, according to the power supply system of the present invention, when the disconnection is detected, the first power supplying portion and the second power supplying portion are caused to operate. Therefore, a power supply for use in all equipments that are connected to the power supply bus can be promptly revived.

### BRIEF DESCRIPTION OF THE DRAWINGS

FIGS. 1A and 1B are block diagrams showing functionally a power supply system according to the present invention;

FIG. 2 is a block diagram showing a configuration of a power supply system according to a first embodiment;

FIG. 3 is a block diagram showing a situation immediately after a disconnection occurs in the power supply bus;

FIG. 4 is a block diagram showing a temporarily recovered situation;

FIG. 5 is a block diagram showing a configuration of a power supply system according to a second embodiment; and

FIG. 6 is a block diagram showing a situation after a disconnection occurs in the power bus.

### DETAILED DESCRIPTION OF THE PREFERRED EMBODIMENTS

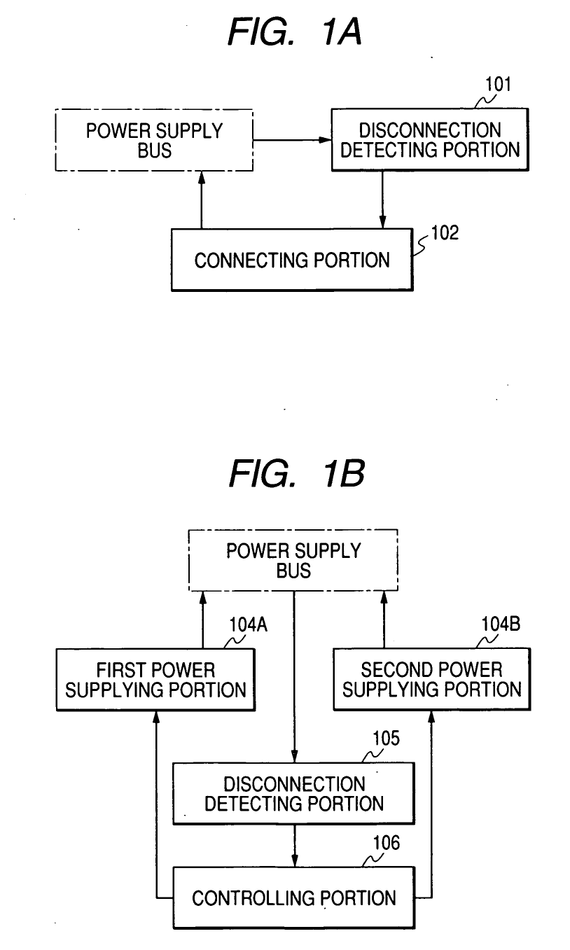

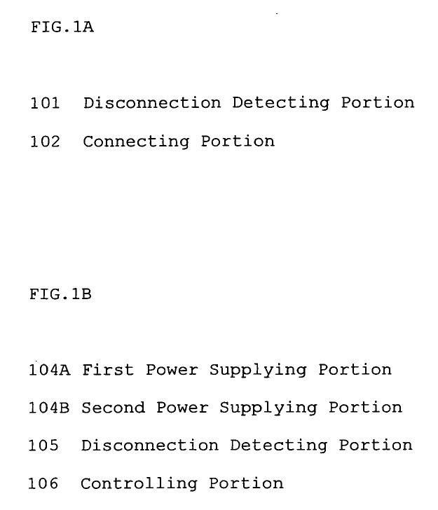

FIGS. 1A and 1B are block diagrams showing functionally a power supply system according to the present invention.

In FIG. 1A, a disconnection detecting portion 101 detects a disconnection of a power supply bus. A connecting portion 102 connects both ends of the power supply bus mutually when the disconnection is detected by the disconnection detecting portion 101.

In FIG. 1B, a first power supplying portion 104A is connected to one end side of the power supply bus and then connected to field equipments via the power supply bus. A second power supplying portion 104B is connected to the other end side of the power supply bus and then connected to the field equipments via the power supply bus. A disconnection detecting portion 105 detects a disconnection of a communication bus. A controlling portion 106 causes the first power supplying portion 104A and the second power supplying portion 104B to operate when the disconnection is detected by the disconnection detecting portion 105.

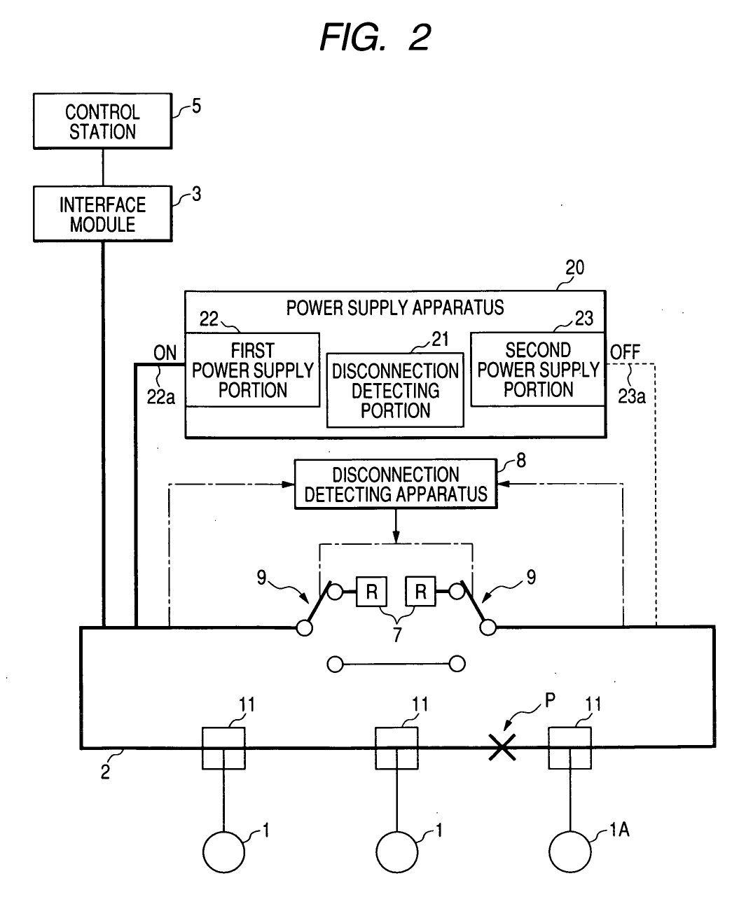

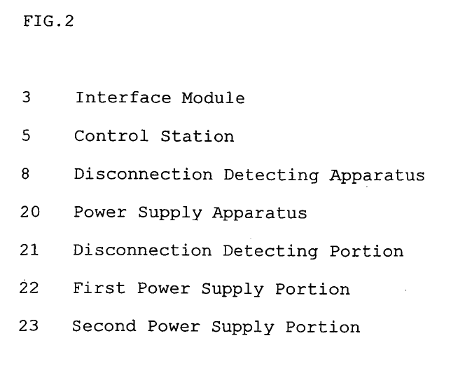

Embodiments of the power supply system according to the present invention will be explained with reference to FIG. 2 to FIG. 6 hereunder.

### First Embodiment

FIG. 2 is a block diagram showing a configuration of a power supply system according to a first embodiment.

As shown in FIG. 2, the power supply system of the present embodiment includes a field bus 2 consisting of two conductive wires to connect field equipments 1, 1, . . . , in common, and an interface module 3 connected to the field equipments 1, 1, . . . via the field bus 2. As shown in FIG. 2, each field equipment 1 is connected to the field bus 2 via a terminal base 11.

A power supply apparatus 20 is connected to the field bus 2 via a power supply line 22a and a power supply line 23a. The power supply apparatus 20 has a disconnection detecting portion 21 for detecting the disconnection of the field bus 2, a first power supply portion 22 for outputting a power supply voltage to the power supply line 22a, and a second power supply portion 23 for outputting a power supply voltage to the power supply line 23a. In this manner, the power supply apparatus 20 is connected to respective field equipments 1 via the field bus 2 and functions as the power supply apparatus common to all field equipments 1. The field bus 2 functions as the power supply bus common to all field equipments 1. A power supply voltage is applied to two conductive lines of the field bus 2.

A method of detecting the disconnection of the field bus 2 in the disconnection detecting portion 21 of the power supply apparatus 20 is not particularly limited. For example, the disconnection can be detected based on a voltage of the power supply line 22a or the power supply line 23a. Also, for example, a detect signal whose amplitude is minute to such an extent that an operation of the system is not disturbed and whose frequency is high may be output from the first power supply portion 22 to the power supply line 22a to superpose on the power supply voltage, and then this detect signal may be detected in the second power supply portion 23. In this case, it can be decided that the disconnection occurs in the field bus 2 unless the detect signal is detected in the second power supply portion 23.

As shown in FIG. 2, the field bus 2 is connected to a control station 5 via the interface module 3. The control station 5 communicates with the field equipments 1, 1, . . . via the field bus 2 and the interface module 3, and controls the field equipments 1, 1, . . . . Also, the field equipments 1, 1, . . . can communicate mutually via the field bus 2. As shown in FIG. 2, a terminating resistor 7 to secure the normal communication condition is provided to both ends of the field bus 2 respectively. In this manner, the field bus 2 functions as the communication bus. The communication is carried out by superposing communication data (digital signal) on the power supply voltage of the power supply apparatus 20 over the field bus 2.

Also, in the present embodiment, a disconnection detecting apparatus 8 for detecting the disconnection of the field bus 2 by comparing signals at both ends of the field bus 2 with each other, and switches 9 for connection both ends of the field bus 2 are provided. The disconnection detecting apparatus 8 always compares signal waveforms at both ends of the field bus 2 with each other. This disconnection detecting apparatus 8 decides that the field bus 2 is disconnected when a difference between the signal waveforms is detected, and then switches the switches 9. When the disconnection of the field bus 2 is detected by the disconnection detecting apparatus 8, the switches 9 cut off the terminating resistor 7 from both ends of the field bus 2 respectively, and then connect both ends of the field bus 2 mutually.

In addition, the terminating resistor is built in the terminal base 11. The terminal base 11 has a function of connecting the terminating resistor to the field bus 2 in close vicinity of the cut-off portions when the field bus 2 is cut off.

Next, an operation of the present embodiment will be explained hereunder.

As shown in FIG. 2, in a normal operation of the field bus 2, the interface module 3 and all the field equipments 1 are connected mutually via the field bus 2. Also, only the first power supply portion 22 of the power supply apparatus 20 is functioning (is turned ON), and the power supply voltage is supplied to all the field equipments 1 via the power supply line 22a and the field bus 2.

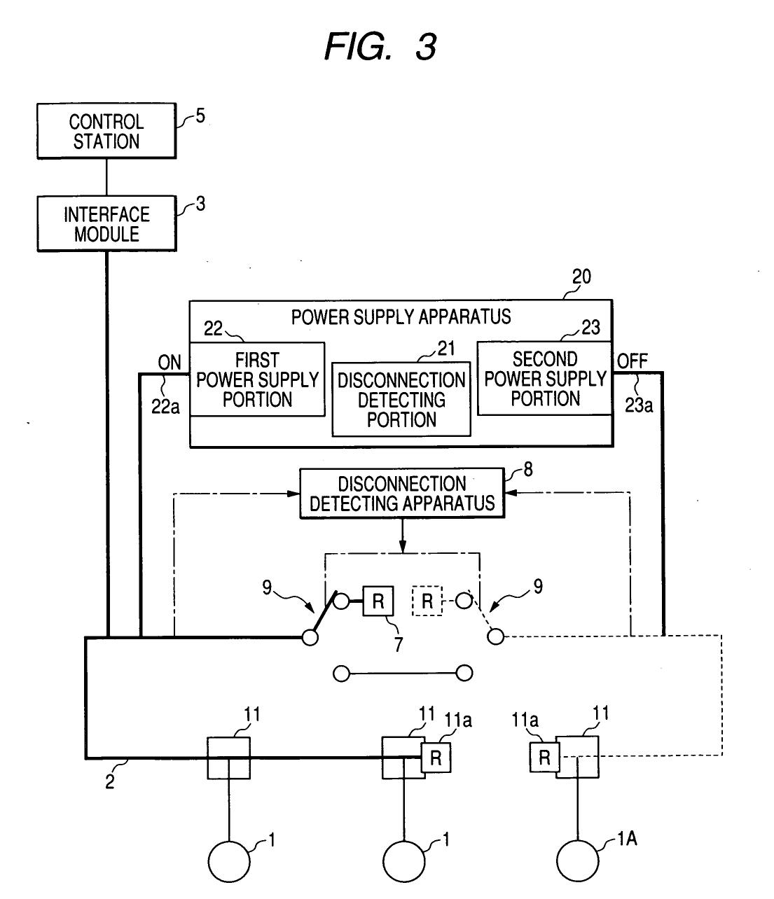

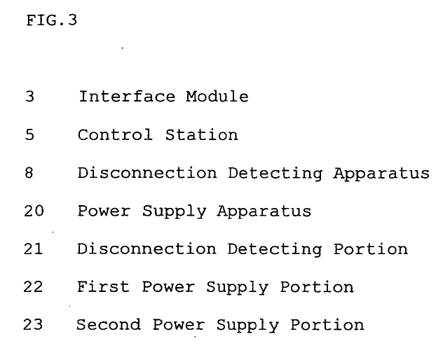

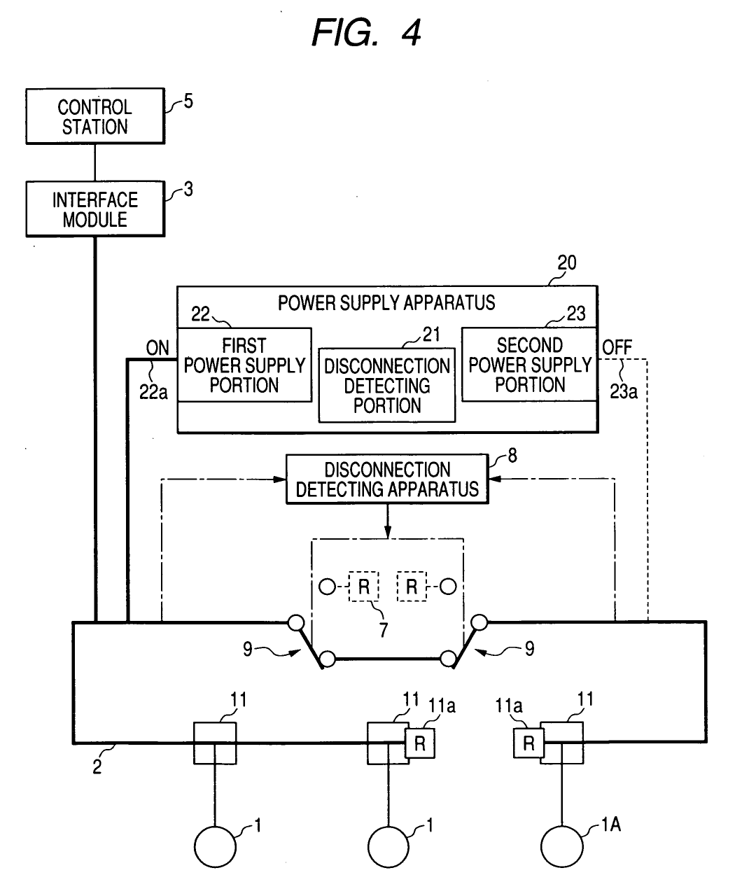

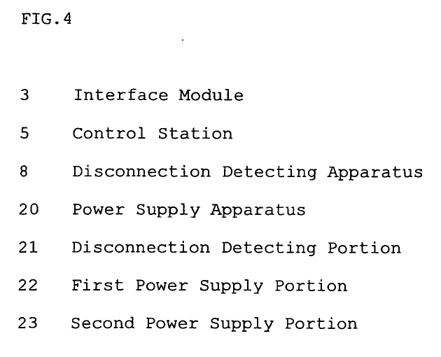

FIG. 3 is a block diagram showing a situation immediately after the disconnection occurs at a portion P (FIG. 2) of the field bus 2, and FIG. 4 is a block diagram showing a temporarily recovered situation.

As shown in FIG. 3, when the disconnection occurs, the disconnection detecting portion 21 of the power supply apparatus 20 detects this disconnection immediately after the disconnection is caused. Therefore, the second power supply portion 23 acts and then the power supply voltage is supplied to a field equipment 1A via the power supply line 23a. Since a function of avoiding an influence of a short-time power supply halt is provided to the field equipment 1, the field equipments 1 including the field equipment 1A are never brought into their function halt state.

Also, as shown FIG. 3, when the field bus 2 is disconnected, the terminal base 11 located near the cut portion P detects the disconnection of the field bus 2, and then connects a terminating resistor 11a to the field bus 2.

Thus, as shown FIG. 3, the field bus 2 is divided into two segments immediately after the disconnection occurs. Therefore, the field equipment 1A is separated from the interface module 3 and other field equipments 1 and is unable to execute the communication. However, the feeding of the power supply voltage from the power supply apparatus 20 to the field equipments 1 including the field equipment 1A is still continued substantially. Therefore, the field equipment 1 carries out predetermined processes such as holding of final output values, and the like by a fail-safe function provided to the field equipment 1 until the communication condition is returned to its normal communication state, and thus a safety condition can be ensured.

As shown FIG. 4, the disconnection detecting apparatus 8 when detects the disconnection of the field bus 2 switches the switches 9. As a result, both ends of the field bus 2 are connected mutually and also the terminating resistors 7 are disconnected from the field bus 2.

In a state in FIG. 4, since the first power supply portion 22 and the field equipment 1A are connected via the switches 9, such a connection condition can be ensured that the power supply voltage can be supplied to all the field equipments 1 only from the first power supply portion 22. Also, since the interface module 3 and all the field equipments 1 are connected mutually via the switches 9 and the field bus 2, the communication condition is returned to its normal communication state. In contrast, the disconnection detecting portion 21 detects that the cut state of the field bus 2 has been eliminated, based on the switching of the switches 9 and halts the function of the second power supply portion 23. As a result, as in the normal operation, the first power supply portion 22 can supply the power supply voltage to all the field equipments 1.

As described above, in the present embodiment, when the disconnection of the field bus 2 is detected, both ends of the field bus 2 are connected by the switches 9. Therefore, the supply of the power supply voltage can be recovered promptly. Also, the disconnection detecting portion 21 detects the disconnection immediately after the disconnection is caused, and then both the first power supply portion 22 and the second power supply portion 23 function until the switching of the switches 9 is completed (FIG. 3). Therefore, the power supply voltage can be supplied to all the field equipments 1 substantially continuously.

### Second Embodiment

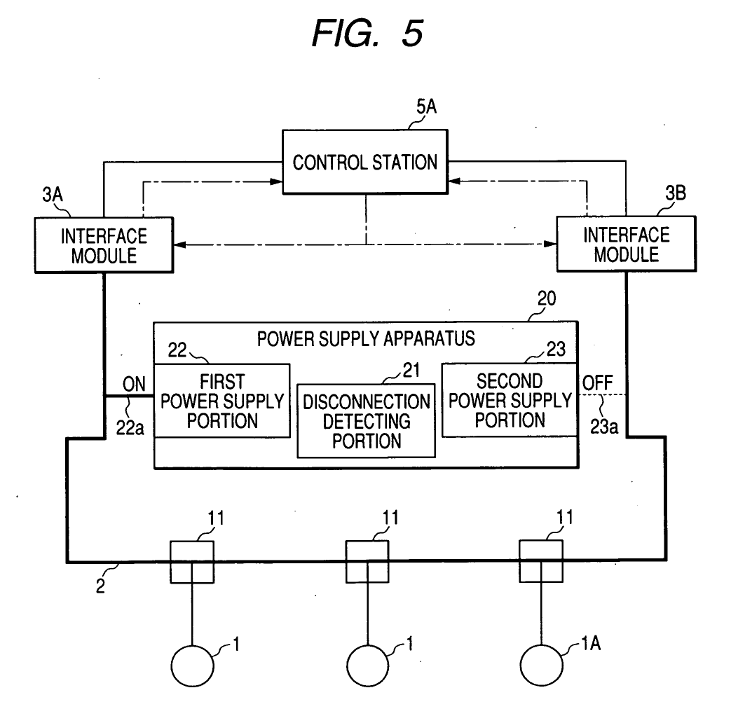

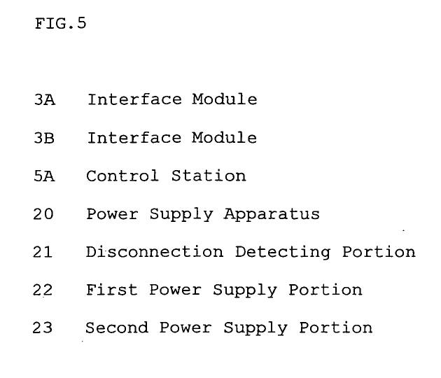

FIG. 5 is a block diagram showing a configuration of a power supply system according to a second embodiment. The same reference symbols are affixed to the same elements as those in the first embodiment.

As shown in FIG. 5, in the power supply system of the present embodiment, an interface module 3A and an interface module 3B are connected to both ends of the field bus 2 respectively.

As shown in FIG. 5, only the first power supply portion 22 acts in the normal operation of the power supply apparatus 20. Thus, the power supply voltage is supplied to all the field equipments 1 via the power supply line 22a and the field bus 2.

Also, in the normal operation, the interface module 3A is in its operation state and the interface module 3B is in its standby state. Thus, merely the interface module 3A is operating. In this event, both the interface module 3A and the interface module 3B send out segment information acquired at both ends of the field bus 2 respectively to an upper control station 5A at any time.

The control station 5A compares both segment information mutually, and decides that the disconnection is caused if these information are different.

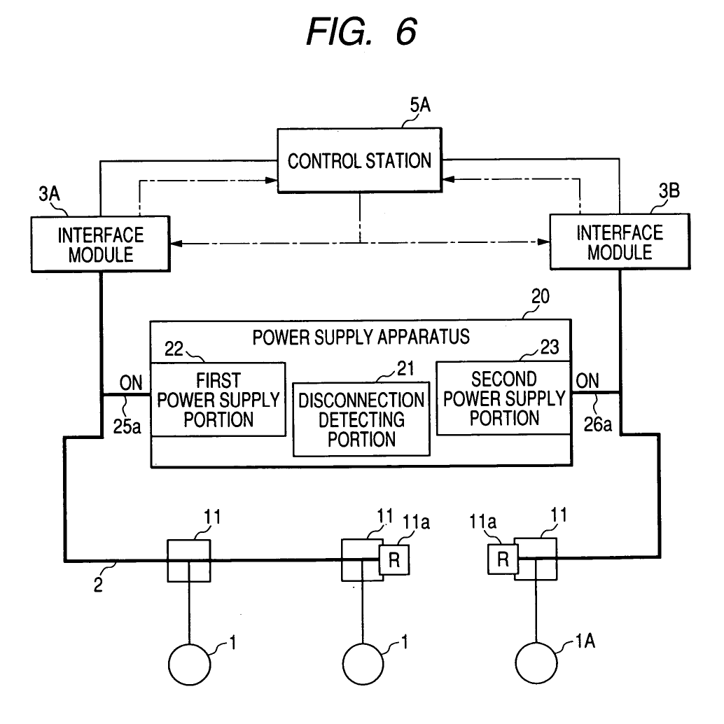

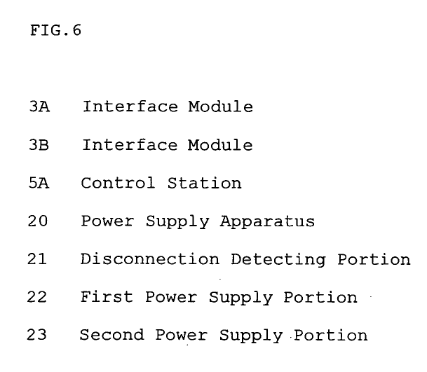

FIG. 6 is a block diagram showing a situation after the disconnection occurs in the field bus 2.

As shown in FIG. 6, when the disconnection occurs, the field bus 2 is divided into two segments, and then two field equipments 1 are connected to the interface module 3A and one field equipment 1A is connected to the interface module 3B. In this case, the disconnection detecting portion 21 of the power supply apparatus 20 detects the disconnection just after the disconnection occurs. Therefore, the second power supply portion 23 operates immediately and thus the second power voltage is supplied to the field equipment 1A via the power supply line 26a. As a result, the power supply voltage is supplied to two segments from the first power supply portion 22 and the second power supply portion 23 respectively. Since a function of avoiding the influence of a short-time power supply halt is provided to the field equipment 1, the field equipments 1 including the field equipment 1A never lapse into a function halt situation.

Also, the terminal base 11 located in vicinity of the cut portion detects the disconnection of the field bus 2 and then connects the terminating resistor 11a to the field bus 2.

When the field bus 2 is cut off, the control station 5A decides that the disconnection occurs, based on both segment information. When it is decided that the disconnection occurs, the control station 5A controls communication data on the field bus 2 via the interface module 3A and the interface module 3B. As a result, the control station 5A equates the information of two segments with each other and maintains the operation similar to the normal operation.

As described above, according to the present embodiment, the disconnection detecting portion 21 detects the disconnection immediately after the disconnection is caused, and then both the first power supply portion 22 and the second power supply portion 23 are caused to operate. Therefore, the power supply voltage can be supplied to all the field equipments 1 substantially continuously.

As the power supply apparatus 20 in respective embodiments, any power supply apparatus may be employed if the power supply apparatus is constructed such that the power supply voltage can be supplied to two separated segments independently. The first power supply portion 22 and the second power supply portion 23 may be provided as the integral power supply apparatus, or the first power supply portion 22 and the second power supply portion 23 may be provided separately. Also, the first power supplying portion 104A and the second power supplying portion 104B (FIG. 1B) may be constructed by combining a single power supply apparatus with a circuit that controls the supply of the power supply voltage to respective segments.

In above embodiments, an example (field bus) in which the power supply bus is used as both the power supply bus and the communication bus is exemplified. But the present invention is not limited to the case where such bus is used. The present invention can be applied to all the power supply systems that are constructed by connecting the equipments and the power supply apparatus via the power supply bus.

An applicable range of the present invention is not limited to the above embodiments. The present invention is not limited to the power supply system that supplies the power supply voltage to the field equipments, but the present invention can be applied universally to the power supply system for use in all equipments.

What is claimed is:

1. A power supply system in which a power supply apparatus and respective equipments are connected to a common power supply bus, comprising:
a disconnection detecting portion which detects a disconnection of the power supply bus; and
a connecting portion which connects both ends of the power supply bus when the disconnection is detected by the disconnection detecting portion.

2. A power supply system in which a power supply apparatus and respective equipments are connected to a common power supply bus, comprising:
a first power supplying portion connected to one end side of the power supply bus and connected to the equipments via the power supply bus;
a second power supplying portion connected to other end side of the power supply bus and connected to the equipments via the power supply bus;
a disconnection detecting portion which detects the disconnection of a communication bus; and
a controlling portion which causes the first power supplying portion and the second power supplying portion to function when the disconnection is detected by the disconnection detecting portion.

3. The power supply system according to claim 1, wherein the disconnection detecting portion detects the disconnection based on a voltage of the power supply bus.

4. The power supply system according to claim 2, wherein the disconnection detecting portion detects the disconnection based on a voltage of the power supply bus.

5. The power supply system according to claim 2, wherein the disconnection detecting portion includes:
a signal outputting portion which outputs a detect signal to the power supply bus from the first power supplying portion; and
a signal receiving portion which receives the detect signal, which propagates through the power supply bus, from the signal outputting portion,
wherein the disconnection detecting portion detects the disconnection based on a reception result in the signal receiving portion.
